(19) United States
(12) Patent Application Publication
(10) Pub. No.: US 2024/0420987 A1
(43) Pub. Date: Dec. 19, 2024

(54) Donor and Transfer Method of Light Emitting Diode Using the Same

(71) Applicant: LG Display Co., Ltd., Seoul (KR)

(72) Inventors: Suhun Lee, Gimpo-si (KR); Hyunmin Park, Paju-si (KR)

(21) Appl. No.: 18/654,575

(22) Filed: May 3, 2024

(30) Foreign Application Priority Data
Jun. 16, 2023 (KR) 10-2023-0077493

(51) Int. Cl. H01L 21/683; H01L 25/075

(52) U.S. Cl. CPC H01L 21/6835; H01L 25/0753

(57) ABSTRACT

According to an aspect of the present disclosure, a donor includes a base substrate; a resin layer which is disposed on the base substrate and includes a plurality of chip bumps; and an airbag layer which is disposed between the base substrate and the resin layer and is configured to be expandable by air injected from the outside. Accordingly, a height of the plurality of chip bumps is adjusted using the airbag layer so that a gap between the plurality of chip bumps and the plurality of light emitting diodes may be removed during the transfer process.

### CROSS-REFERENCE TO RELATED APPLICATION

This application claims the benefit and priority to Republic of Korean Patent Application No.10-2023-0077493 filed in the Republic of Korea on Jun. 16, 2023, the entirety of which is expressly incorporated by reference for all purposes as if fully set forth herein.

### TECHNICAL FIELD

The present disclosure relates to a donor and a transfer method of a light emitting diode using the same, and more particularly, for example, without limitation, to a donor and a transfer method of a light emitting diode using the same, capable of reducing a non-contact defect of a light emitting diode.

### DESCRIPTION OF THE RELATED ART

Among display devices which are used for a monitor of a computer, a television, or a cellular phone, there are an organic light emitting display device (OLED) which is a self-emitting device, a plasma display device (PDP), a field emission display device (FED), a micro LED (Micro Light Emitting Diode) display device, and a liquid crystal display device (LCD) which requires a separate light source (e.g., a blacklight unit). An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast-lighting speed, excellent luminous efficiency, and a strong impact resistance so that a stability is excellent and an image having a high luminance may be displayed. The display device including an LED is manufactured by transferring an LED using a donor.

The description provided in the description of the related art section should not be assumed to be prior art merely because it is mentioned in or associated with the description of the related art section. The description of the related art section may include information that describes one or more aspects of the subject technology.

### SUMMARY

An object to be achieved by the present disclosure is to provide a donor and a transfer method of a light emitting diode using the same, capable of reducing a non-contact defect of a light emitting diode.

Another object to be achieved by the present disclosure is to provide a donor which compensates for a thickness irregularity of a resin layer and a plurality of chip bumps and a transfer method of a light emitting diode using the same.

Another object to be achieved by the present disclosure is to provide a donor which easily injects air from the head directly to the airbag layer and a transfer method of a light emitting diode using the same.

Still another object to be achieved by the present disclosure is to provide a donor which selectively injects air to each of a plurality of areas of an airbag layer to improve a process efficiency and a transfer method of a light emitting diode using the same.

Objects of the present disclosure are not limited to the above-mentioned objects, and other objects, which are not mentioned above, can be clearly understood by those skilled in the art from the following descriptions.

According to an aspect of the present disclosure, a donor may include a base substrate; a resin layer which is disposed on the base substrate and includes a plurality of chip bumps; and an airbag layer which is disposed between the base substrate and the resin layer and is configured to be expandable by air injected from the outside. Accordingly, a height of the plurality of chip bumps is adjusted using the airbag layer so that a gap between the plurality of chip bumps and the plurality of light emitting diodes may be removed during the transfer process.

According to an aspect of the present disclosure, a transfer method of a light emitting diode using a donor may include loading, a temporary substrate with a plurality of light emitting diodes disposed on a top surface, on a stage, and fixing a donor to a head; bonding the temporary substrate and the donor by moving the head to the stage; injecting air to an airbag layer of the donor; and moving the head to separate the temporary substrate and the donor. Accordingly, the air is injected to the airbag layer to allow the light emitting diode to be in contact with the donor and minimize or at least reduce the non-transferring defect of the light emitting diode.

Other detailed matters of the example embodiments are included in the detailed description and the drawings.

According to the present disclosure, in a transfer process of a plurality of light emitting diodes using a donor, a non-contact defect of a donor and a plurality of light emitting diodes is minimized or at least reduced to optimize a transfer process.

According to the present disclosure, an airbag layer is formed in a donor to compensate a thickness irregularity of a resin layer and a plurality of chip bumps to minimize or at least reduce a non-transferring defect of a plurality of light emitting diodes.

According to the present disclosure, a hole is formed in a base substrate to directly inject air onto one surface of an airbag layer, thereby reducing a thickness of a donor and simplifying an air injection process.

According to the present disclosure, the air is selectively injected to a plurality of areas of an airbag layer depending on a situation to improve a transfer efficiency of a light emitting diode.

The effects according to the present disclosure are not limited to the contents exemplified above, and more various effects are included in the present specification. Additional features and aspects of the disclosure are set forth in part in the description that follows and in part will become apparent from the description or can be learned by practice of the inventive concepts provided herein. Other features and aspects of the inventive concepts can be realized and attained by the structures pointed out in the present disclosure, or derivable therefrom, and the claims hereof as well as the appended drawings.

It is to be understood that both the foregoing general description and the following detailed description are explanatory examples and are intended to provide further explanation of the inventive concepts as claimed.

### BRIEF DESCRIPTION OF THE DRAWINGS

The accompanying drawings provide a further understanding of the disclosure and can be incorporated in and constitute a part of the disclosure, illustrate embodiments of the disclosure and together with the description serve to explain various principles of the disclosure.

The above and other aspects, features and other advantages of the present disclosure will be more clearly understood from the following detailed description taken in conjunction with the accompanying drawings, in which:

FIG. 1 is a plan view of a donor according to an example embodiment of the present disclosure;

FIG. 2 is a cross-sectional view of a donor according to an example embodiment of the present disclosure;

FIG. 3 is a plan view of an airbag layer of a donor according to an example embodiment of the present disclosure;

FIGS. 4A and 4B are process diagrams for explaining a transfer method of a light emitting diode using a donor according to an example embodiment of the present disclosure;

FIGS. 4C and 4D are enlarged cross-sectional views for explaining a process of improving a non-contact defect using an airbag layer during a transfer process of a light emitting diode using a donor according to an example embodiment of the present disclosure;

FIG. 5 is a cross-sectional view of a donor according to another example embodiment of the present disclosure;

FIG. 6 is a cross-sectional view of a donor and a head according to another example embodiment of the present disclosure;

FIG. 7 is a plan view of an airbag layer of a donor according to still another example embodiment of the present disclosure;

FIG. 8 is a plan view of an airbag layer of a donor according to still another example embodiment of the present disclosure;

FIG. 9A is an image inspecting a transfer process result using a donor according to a comparative embodiment; and

FIG. 9B is an image inspecting a transfer process result using a donor according to an example embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted or can be briefly provided. The progression of processing steps and/or operations described is an example; however, the sequence of steps and/or operations is not limited to that set forth herein and can be changed as is known in the art, with the exception of steps and/or operations necessarily occurring in a particular order Like reference numerals designate like elements throughout. Names of the respective elements used in the following explanations can be selected only for convenience of writing the specification and can be thus different from those used in actual products.

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, areas, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted or may be briefly provided to avoid unnecessarily obscuring the subject matter of the present disclosure. The terms such as “including,” “having,” “constitute,” “make up of,” “formed of,”, “comprising” and “consist of” used herein are generally intended to allow other components to be added unless the terms are used with the term “only”. Any references to singular may include plural unless expressly stated otherwise.

Any implementation described herein as an “example” is not necessarily to be construed as preferred or advantageous over other implementations.

Components are interpreted to include an ordinary error range or tolerance range even if there is no explicit description of such an error or tolerance range.

When the position relation between two parts is described using the terms such as “on”, “over,” “above”, “below”, “beside,” “beneath,” “near,” “close to,” “adjacent to,” and “next”, one or more parts may be positioned between the two parts unless the terms are used with the term “immediately”, “closely”, or “directly”. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

When temporally relative terms, such as “after,” “subsequent,” “following,” “next” and “before” are used to define a temporal relationship, a non-continuous situation can be included unless a more limiting term, such as “just,” “immediately” or “directly” is used.

When an element or layer is disposed “on” another element or layer, another layer or another element may be directly on the other element or interposed therebetween.

Although the terms “first”, “second”, “A”, “B”, “(a)”, “(b)” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawings are illustrated for convenience of description, and the present disclosure is not limited to the size and the thickness of the component illustrated.

The features of various embodiments of the present disclosure can be partially or entirely coupled to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

The expression that an element is “connected,” “coupled,” or “adhered” to another element or layer the element or layer can not only be directly connected or adhered to another element or layer, but also be indirectly connected or adhered to another element or layer with one or more intervening elements or layers “disposed,” or “interposed” between the elements or layers, unless otherwise specified.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first item, a second item, and a third item” encompasses the combination of all three listed elements, combinations of any two of the three elements, as well as each individual element, the first element, the second element, and the third element.

Hereinafter, various example embodiments of the present disclosure will be described in detail with reference to the accompanying drawings. For convenience of description, a scale of each of elements illustrated in the accompanying drawings differs from a real scale, and thus, is not limited to a scale illustrated in the drawings.

Hereinafter, the donor and transfer method using the same according to various example embodiments of the present disclosure will be described in detail with reference to accompanying drawings. All the components of each donor according to all embodiments of the present disclosure are operatively coupled and configured.

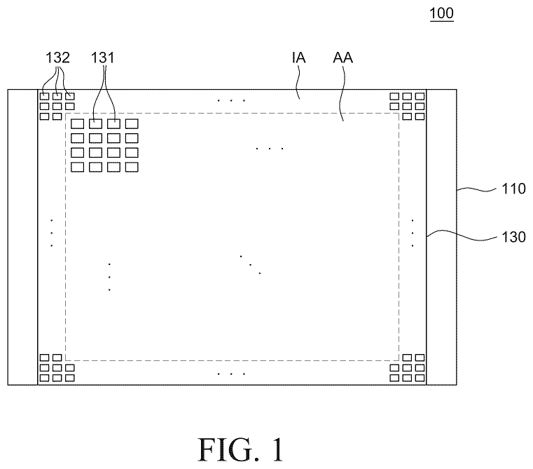

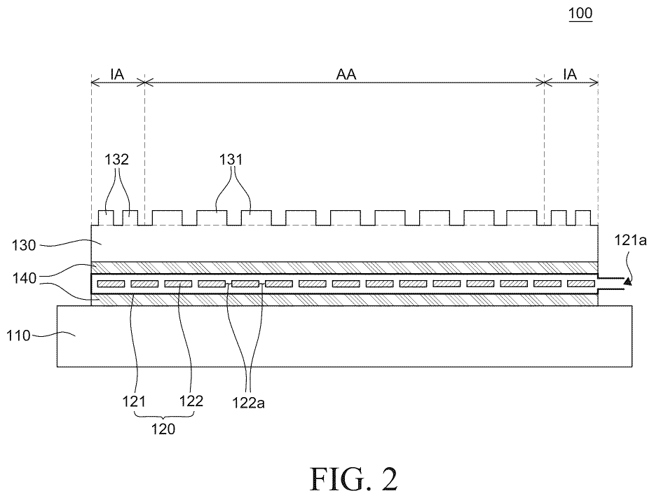

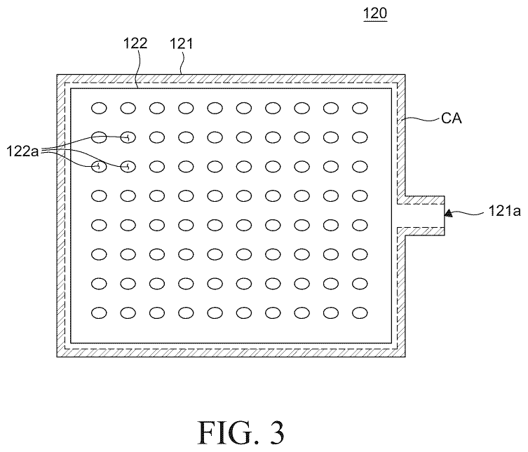

FIG. 1 is a plan view of a donor according to an example embodiment of the present disclosure. FIG. 2 is a cross-sectional view of a donor according to an example embodiment of the present disclosure. FIG. 3 is a plan view of an airbag layer of a donor according to an example embodiment of the present disclosure. In FIG. 3, for the convenience of description, a punching plate 122 and a plurality of holes 122a disposed in a cushion unit 121 are illustrated with solid lines.

Referring to FIGS. 1 and 2, the donor 100 is a member which transfers a plurality of light emitting diodes LED to a target substrate. The donor 100 may transport a plurality of light emitting diodes LED disposed on a wafer or a temporary substrate TS to a target substrate, such as a substrate of a display device. For example, the donor 100 is bonded onto the wafer or the temporary substrate TS on which the plurality of light emitting diodes LED are disposed to transfer the plurality of light emitting diodes LED to the donor 100. Further, the donor 100 to which the plurality of light emitting diodes LED are temporarily attached is bonded to the target substrate to transfer the plurality of light emitting diodes LED to the target substrate. Therefore, the plurality of light emitting diodes LED are transferred from the temporary substrate TS to the target substrate using the donor 100 to form an electronic product, such as a display device.

At this time, the light emitting diode LED may be an LED or a micro-LED.

The donor 100 includes a base substrate 110, a plurality of adhesive layers 140, an airbag layer 120, a resin layer 130, a plurality of chip bumps 131, and a plurality of dummy bumps 132.

The base substrate 110 is a configuration for supporting various components included in the donor 100. The base substrate 110 is formed of a material at least harder than the resin layer 130 to minimize or at least reduce a warpage of the resin layer 130. The base substrate 110 supports the resin layer 130 which is relatively flexible more than the base substrate 110, the plurality of chip bumps 131 and the plurality of dummy bumps 132 disposed on the resin layer 130 to minimize or at least reduce the deformation thereof during the transfer process. The base substrate 110 is formed to have the largest thickness among configurations of the donor 100 to support the other configurations of the donor 100. For example, the base substrate 110 is formed to have a thickness of approximately 500 μm. Further, the base substrate 110 has a rigidity and may be formed of a transparent material. For example, the base substrate 110 is formed of glass or a plastic material such as polycarbonate (PC) or polyethylene terephthalate (PET), but is not limited thereto.

The resin layer 130 is disposed on the airbag layer 120. The resin layer 130 may support the plurality of chip bumps 131 to which the plurality of light emitting diodes LED are attached, during the transfer process. The resin layer 130 is formed by a polymer resin having viscoelasticity, for example, the resin layer 130 is configured by poly dimethyl siloxane (PDMS), poly urethane acrylate (PUA), polyethylene glycol (PEG), polymethylmethacrylate (PMMA), polystyrene (PS), epoxy resin, urethane resin, or acrylic resin. However, it is not limited thereto.

The resin layer 130 includes an active area AA and an inactive area IA. The active area AA is an area in which the plurality of chip bumps 131 to be attached with the plurality of light emitting diodes LED are disposed and may be disposed so as to correspond to the wafer 200 or the temporary substrate TS, or the target substrate during the transfer process.

The inactive area IA is disposed so as to enclose or surround the active area AA. In the inactive area IA, configurations for stably performing the transfer process of the donor 100 may be disposed. For example, in the inactive area IA, a plurality of dummy bumps 132 which stably fixes the donor 100 when the donor 100 is bonded to the other configuration, may be disposed.

The plurality of chip bumps 131 is disposed on the resin layer 130 in the active area AA. The plurality of chip bumps 131 is bumps to which the plurality of light emitting diodes LED are temporarily attached during the transfer process and extends from one surface of the resin layer 130. The plurality of chip bumps 131 may be integrally formed with the resin layer 130 and may be formed of a polymer material having viscoelasticity, which is the same as the resin layer 130. For example, the plurality of chip bumps 131 may be formed of poly dimethyl siloxane (PDMS), poly urethane acrylate (PUA), polyethylene glycol (PEG), polymethylmethacrylate (PMMA), polystyrene (PS), epoxy resin, urethane resin, or acrylic resin, but is not limited thereto.

The plurality of light emitting diodes LED are temporarily attached onto top surfaces of the plurality of chip bumps 131. During the transfer process, the plurality of light emitting diodes LED on the wafer, or the temporary substrate TS is transferred to the donor 100 to be temporarily attached onto the top surface of the chip bump 131 having viscoelasticity. Thereafter, the plurality of light emitting diodes LED attached on the chip bump 131 of the donor 100 may be transferred to the target substrate. At this time, the number of light emitting diodes LED to be disposed on one chip bump 131 may vary depending on the design, but is not limited thereto.

The plurality of dummy bumps 132 is disposed on the resin layer 130 in the inactive area IA. The plurality of dummy bumps 132 improves the bonding strength of the donor 100 and a counter substrate (e.g., the temporary substrate TS or the target substrate) during the transfer process and may minimize or at least reduce the deformation of the plurality of chip bumps 131 due to the shock which is applied to the donor 300. For example, when the plurality of light emitting diodes LED are transferred from the temporary substrate TS to the donor 100 by bonding the temporary substrate TS and the donor 100, the plurality of dummy bumps 132 in the inactive area IA is in contact with the temporary substrate TS. By doing this, the entire contact area of the temporary substrate TS and the donor 100 may be increased. Accordingly, the donor 100 can be stably bonded to the temporary substrate TS by the plurality of dummy bumps 132 to support the resin layer 130 and the chip bump 131 of the donor 100 so as not to be deformed by the external shock. The plurality of dummy bumps 132 may be formed to have a different shape and a different size from those of the chip bump 131, but is not limited thereto.

In addition, even though it is not illustrated in the drawing, a plurality of alignment bumps, a plurality of alignment patterns, and a plurality of displacement measurement areas may be further disposed in the inactive area IA. For example, a plurality of alignment bumps to which an alignment key is transferred or an alignment pattern which is a mark to be aligned with an alignment pattern of the counter substrate is formed in the inactive area IA to align the donor 100 and the counter substrate during the transfer process. Further, the displacement measurement area which is an empty space in which the plurality of dummy bumps 132, the alignment bump, or the alignment pattern is not disposed is formed in the inactive area IA to allow the laser to be transmitted to measure the parallelism of the donor 100.

Next, an adhesive layer 140 is disposed between the base substrate 110 and the airbag layer 120 and between the airbag layer 120 and the resin layer 130. The adhesive layer 140 attaches the base substrate 110, the airbag layer 120, and the resin layer 130 to each other. The adhesive layer 140 may be formed of a material having adhesiveness and for example, may be formed of an optical clear adhesive (OCA) or a pressure sensitive adhesive (PSA), but is not limited thereto.

Referring to FIGS. 1 to 3 together, the airbag layer 120 is disposed between the base substrate 110 and the resin layer 130. The airbag layer 120 is configured to expand when air is injected and the expanding airbag layer 120 applies a pressure to the resin layer 130 to push the resin layer 130 and the plurality of chip bumps 131 in a direction from the bottom of the base substrate to the top of the base substrate 110. For example, a height of the plurality of chip bumps 131 may vary depending on an amount of air which is injected to the airbag layer 120. The airbag layer 120 includes a cushion unit 121 including an air inlet 121a and the punching plate 122 disposed in the cushion unit 121.

The cushion unit 121 is an elastic membrane that may expand when air is injected through the air inlet 121a or contract when air is discharged through the air inlet 121a. In order to contract and expand the cushion unit 121, the air inlet 121a may be connected to a pump which may inject or discharge the air. The cushion unit 121 may be a membrane formed of a material having an elasticity, for example, a rubber. Further, the cushion unit 121 may be formed with a small thickness to easily expand by the air and for example, may be formed of a rubber membrane with a thickness of approximately 25 μm.

The punching plate 122 having a plurality of holes 122a is disposed in the cushion unit 121. The punching plate 122 disposed in the cushion unit 121 may be formed with a shape corresponding to a planar shape of the cushion unit 121. The punching plate 122 separates a top surface portion and a bottom surface portion of the cushion unit 121 so as not to be adhered so that when the air is injected into the cushion unit 121, the cushion unit 121 may easily expand. Further, the punching plate 122 includes a plurality of holes 122a to reduce contact areas with the top surface portion and the bottom surface portion of the cushion unit 121 to minimize or at least reduce the sticking of the cushion unit 121 to the punching plate 122. Further, a fluorine coating layer with a low coefficient of friction may be further formed on the surface of the punching plate 122 so that the punching plate 122 and the cushion unit 121 are not easily attached. For example, the punching plate 122 is formed of a material such as stainless use steel (SUS) and is formed with a rigid plate having a small thickness of approximately 50 μm, but is not limited thereto.

The remaining part of the cushion unit 121 excluding the air inlet 121a may be sealed. At this time, the cushion unit 121 may not be integrally formed initially, but parts which cover both surfaces of the punching plate 122 are separately formed and the both surface portions of the cushion unit 121 are connected in the remaining part excluding the air inlet 121a to form the cushion unit 121. For example, a top surface portion and a bottom surface portion of the cushion unit 121 are separately formed and the punching plate 122 may be disposed between the separated top surface portion and bottom surface portion. Further, the top surface portion and the bottom surface portion may be connected in a connection area CA of the top surface portion and the bottom surface portion. At this time, the connection area CA may be a remaining edge of the cushion unit 121 excluding a part corresponding to the air inlet 121a. An adhesive is applied in the connection area CA corresponding to an edge of the bottom surface portion and an edge of the top surface portion and the connection area CA is heated and pressurized to connect the bottom surface portion and the top surface portion. Accordingly, the top surface portion and the bottom surface portion of the cushion unit 121 which covers both surfaces of the punching plate 122 are separately formed. After placing the bottom surface portion, the punching plate 122, and the top surface portion in this order, the bottom surface portion and the top surface portion are connected to form the cushion unit 121 in which the punching plate 122 is disposed.

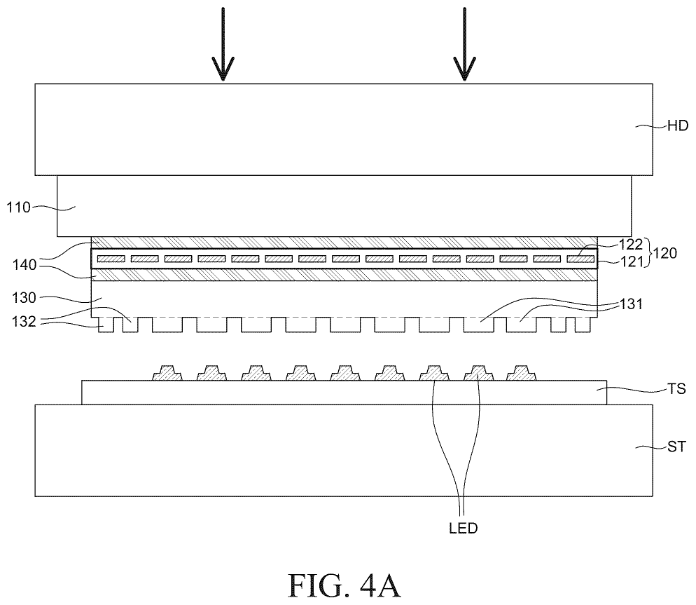

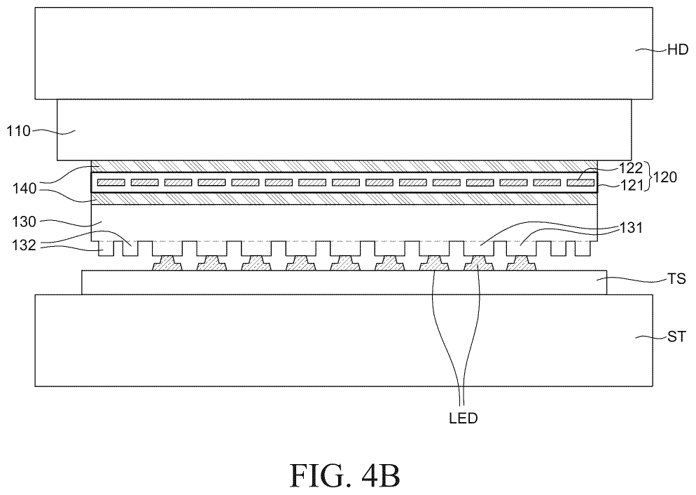

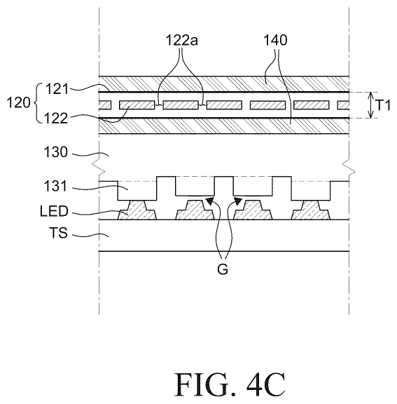

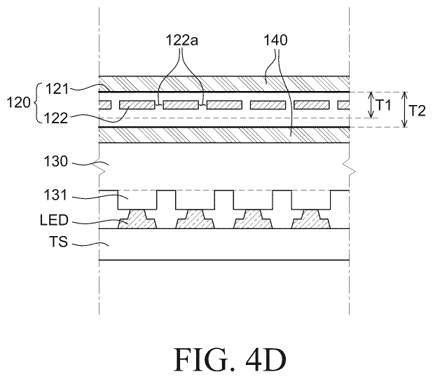

Further, the position of the resin layer 130 and the plurality of chip bumps 131 disposed on the cushion unit 121 is modified in accordance with the modification of the cushion unit 121. For example, when the air is injected to expand the cushion unit 121, the cushion unit 121 applies the pressure to the resin layer 130 and the plurality of chip bumps 131 disposed on the cushion unit 121 to push the resin layer 130 and the plurality of chip bumps 131 in a direction from the bottom of the base substrate to the top of the base substrate 110. The cushion unit 121 expands to reduce the non-attachment probability or defect of the plurality of chip bumps 131 and the plurality of light emitting diodes LED, which will be described below in detail with reference to FIGS. 4A to 4D.

Hereinafter, a transfer method of a light emitting diode LED using a donor 100 according to an example embodiment of the present disclosure will be described with reference to FIGS. 4A to 4D.

FIGS. 4A and 4B are process diagrams for explaining a transfer method of a light emitting diode using a donor according to an example embodiment of the present disclosure. FIGS. 4C and 4D are enlarged cross-sectional views for explaining a process of improving a non-contact defect using an airbag layer during a transfer process of a light emitting diode using a donor according to an example embodiment of the present disclosure. In addition, in FIGS. 4A and 4B, for the convenience of description, even though it is illustrated that the temporary substrate TS is disposed on the stage ST, the wafer may be disposed on the stage ST, but is not limited thereto.

Referring to FIG. 4A, in order to transfer the plurality of light emitting diodes LED on the temporary substrate TS to the donor 100, the temporary substrate TS is loaded on the stage ST and the donor 100 is fixed to the head HD.

The temporary substrate TS may be a substrate in which the plurality of light emitting diodes LED manufactured in the wafer is disposed with a specific arrangement. The plurality of light emitting diodes LED are disposed on the temporary substrate TS with a specific arrangement using a method such as a self-assembling method or a selective transfer method. For example, a plurality of assembling lines is formed to self-assemble the plurality of light emitting diodes LED on the temporary substrate TS. Further, the plurality of light emitting diodes LED are aligned with a specific arrangement by an electric field formed in the plurality of assembling lines to be self-assembled. At this time, the light emitting diode LED is dielectrically polarized by the electric field to have a polarity and the dielectrically-polarized light emitting diode LED may move to a specific direction or fixed by dielectrophoreses (DEP), for example, an electric field. Therefore, the plurality of LEDs is self-assembled on the temporary substrate TS with a specific arrangement, for example, an interval corresponding to the plurality of sub pixels of the display device, by the plurality of assembling lines. As another example, some of the plurality of light emitting diodes LED on the wafer or another donor 100 is selectively transferred to the temporary substrate TS so that the plurality of light emitting diodes LED may be disposed on the temporary substrate TS with a specific arrangement.

However, the wafer may be directly disposed on the stage ST in addition to the temporary substrate TS. A crystal layer is grown on the wafer by forming a material, such as gallium nitride GaN, which configures the plurality of light emitting diodes LED, the crystal layer is cut into individual chips and an electrode is formed to form the plurality of light emitting diodes LED. Further, the wafer on which the plurality of light emitting diodes LED are formed is directly loaded on the stage ST to transfer the plurality of light emitting diodes LED on the wafer to the donor 100.

The head HD is a member which moves the donor 100 and the donor 100 may be fixed to the head HD during the transfer process. For example, a suction hole is formed in the head HD to fix the donor 100 by a vacuum-sucking method. The head HD moves the donor 100 to attach the donor 100 to the temporary substrate TS or the target substrate or detach the donor 100 from the temporary substrate TS or the target substrate.

Referring to FIGS. 4A and 4B, the head HD moves to the stage ST to bond the temporary substrate TS and the donor 100 and transfer the plurality of light emitting diodes LED on the temporary substrate TS to the donor 100. In a state in which the temporary substrate TS on which the plurality of light emitting diodes LED are disposed is located on the stage ST, the head HD and the donor 100 move to the temporary substrate TS to attach the plurality of light emitting diodes LED to the donor 100. The donor 100 and the temporary substrate TS are bonded so that the plurality of chip bumps 131 of the donor 100 is in contact with the plurality of light emitting diodes LED to transfer the plurality of light emitting diodes LED from the temporary substrate TS to the donor 100.

In addition, in the donor 100, a material for forming the resin layer 130 is coated and cured in a mold having a groove corresponding to the plurality of chip bumps 131 and the plurality of dummy bumps 132 to integrally form the resin layer 130 and the plurality of chip bumps 131 and the plurality of dummy bumps 132. However, during the process of coating and curing the resin layer 130 in the mold, the resin layer 130 may have different in-surface thicknesses. In this case, there may be a defect that the chip bump 131 which is disposed in an area of the resin layer 130 having a relatively smaller thickness, in the resin layer 130 which is formed with irregular thicknesses is not in contact with the plurality of light emitting diodes LED. Accordingly, the plurality of light emitting diodes LED are not transferred to some chip bump 131 and the display device formed by the transfer process using such a donor 100 includes a defective sub pixel in which the plurality of light emitting diodes LED are not transferred so that the reliability may be degraded.

For example, referring to FIG. 4C, the thicknesses of the resin layer 130 and the plurality of chip bumps 131 are irregularly formed so that some chip bump 131 may not be in contact with the plurality of light emitting diodes LED in some cases. For example, a gap G may be formed between some chip bump 131 and the plurality of light emitting diodes LED. In this state, when the donor 100 is separated from the temporary substrate TS, the plurality of light emitting diodes LED are not transferred to some chip bump 131 of the donor 100 to cause non-transferring defect of the light emitting diode LED.

Therefore, the donor 100 according to the example embodiment of the present disclosure includes an airbag layer 120 to compensate for the in-surface thickness difference of the resin layer 130 and reduce a non-contact defect between the plurality of light emitting diodes LED and the chip bump 131.

Referring to FIG. 4D, when the air is injected to the airbag layer 120 to expand the airbag layer 120, the resin layer 130 and the plurality of chip bumps 131 may protrude toward the stage ST by the airbag layer 120. For example, when a thickness of the airbag layer 120 is T1 before injecting the air to the airbag layer 120, a thickness of the airbag layer 120 after injecting the air may be T2 which is larger than T1.

Further, when the airbag layer 120 disposed between the base substrate 110 having a rigidity and the resin layer 130 having a flexibility expands, the resin layer 130 having flexibility is pushed by the pressure and at least some chip bump 131 may protrude from the existing location. Further, the plurality of chip bumps 131 may be in contact with the plurality of light emitting diodes LED. Therefore, even though the resin layer 130 has the in-surface thickness difference, the plurality of chip bumps 131 is pushed to the plurality of light emitting diodes LED using the airbag layer 120 to allow all the plurality of chip bumps 131 to be in contact with the plurality of light emitting diodes LED.

At this time, an air pressure range of the airbag layer 120 may be set in consideration of physical properties of the resin layer 130 and the plurality of chip bumps. For example, when the plurality of chip bumps 131 have a thickness of approximately 10 μm, the resin layer 130 has a thickness of approximately 190 μm, the resin layer 130 and the plurality of chip bumps 131 are formed of PDMS having a hardness of 24 Hs, a tensile strength of approximately 6.5 Mps, a Young's modulus of approximately 1.35 to 1.93 Mpa (e.g., 1.6 Mpa), and an elongation of approximately 10 to 80% (e.g., 50%), a pressure of air to be injected to the airbag layer 120 may be approximately 0.5 to 3 bar (e.g., 1.5 bar). The air is injected to the airbag layer 120 at the pressure of approximately 0.5 to 3 bar (e.g., 1.5 bar) to easily deform the resin layer 130 and the plurality of chip bumps 131.

In addition, in FIGS. 4A to 4D, it has been described that the airbag layer 120 is used during a process of transferring the plurality of light emitting diodes LED from the temporary substrate TS to the donor 100. However, the airbag layer 120 may also be used to transfer the plurality of light emitting diodes LED from the donor 100 to the target substrate. For example, the target substrate is loaded on the stage ST and the donor 100 to which the plurality of light emitting diodes LED are attached is fixed to the head, and then the plurality of donors 100 and the target substrate are bonded to transfer the plurality of light emitting diodes LED to the target substrate. At this time, the air is injected to the airbag layer 120 to push the resin layer 130 and the plurality of chip bumps 131 toward the target substrate and the plurality of light emitting diodes LED are brought into contact with the target substrate. Accordingly, the plurality of light emitting diodes LED of the donor 100 is brought into contact with the target substrate using the airbag layer 120 to reduce the non-transferring defect of the plurality of light emitting diodes LED from the donor 100 to the target substrate.

Accordingly, the donor 100 according to the example embodiment of the present disclosure includes the airbag layer 120 which pushes the resin layer 130 to reduce the non-contact defect of the plurality of chip bumps 131 and the plurality of light emitting diodes LED. As the resin layer 130 and the plurality of chip bumps 131 are coated and cured in the mold to be formed, there may be an in-surface thickness difference of the resin layer 130. In this case, the light emitting diode LED is not in contact with some of the plurality of chip bumps 131 so that the light emitting diode LED is not transferred. In this case, the resin layer 130 and the plurality of chip bumps 131 are pushed to the stage ST using the airbag layer 120 so that a gap G between the plurality of chip bumps 131 and the plurality of light emitting diodes LED are removed. Further, the non-contact defect of the plurality of chip bumps 131 and the plurality of light emitting diodes LED are reduced. Accordingly, in the donor 100 according to the example embodiment of the present disclosure, the airbag layer 120 for compensating for the thickness irregularity of the resin layer 130 and the plurality of chip bumps 131 are formed to minimize or at least reduce the non-transferring defect of the plurality of light emitting diodes LED. In this case, the airbag layer 120 may also be referred to as thickness compensation layer, thickness variation layer, or thickness uniformization layer, and the present disclosure is not limited thereto.

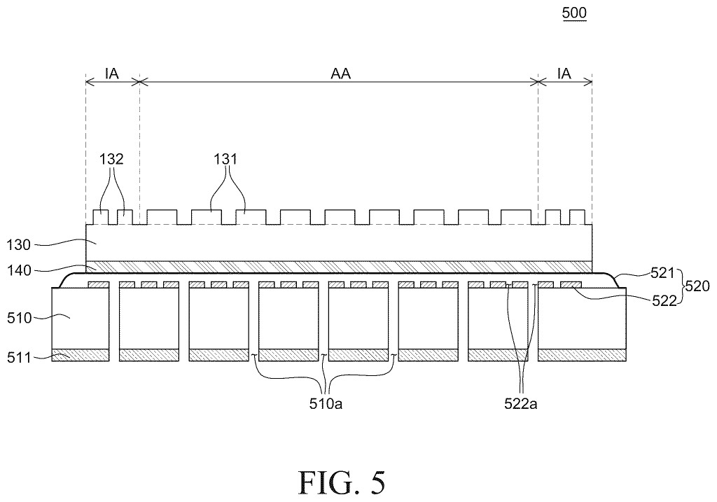

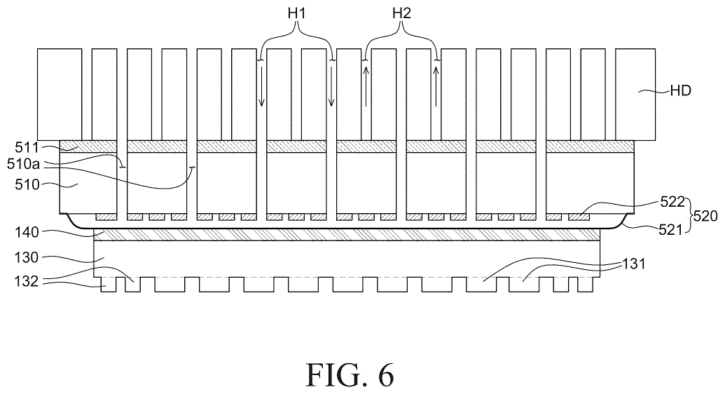

FIG. 5 is a cross-sectional view of a donor according to another example embodiment of the present disclosure. FIG. 6 is a cross-sectional view of a donor and a head according to another example embodiment of the present disclosure. A donor 500 of FIGS. 5 and 6 has a base substrate 510 and an airbag layer 520 having a different structure from that of the donor 100 of FIGS. 1 to 4D, but other configurations are substantially the same so that a redundant description will be omitted or may be briefly provided.

Referring to FIG. 5, the base substrate 510 includes a pad unit 511 formed on a bottom surface of the base substrate 510. The pad unit 511 is a configuration which adheres the head HD and the donor 500 so as not to leak air between the second hole H2 of the head HD and the base substrate 510 when the donor 500 is fixed to the head HD by sucking air through a second hole H2 which is a suction hole. The pad unit 511 may cover a remaining part of the bottom surface of the base substrate 510 excluding a part in which a plurality of injection holes 510a is formed. For example, the pad unit 511 may be a film formed of rubber, but embodiments of the present disclosure are not limited thereto.

A punching plate 522 of an airbag layer 520 is disposed on the base substrate 510. The punching plate 522 is disposed to be in contact with the base substrate 510. Further, the cushion unit 521 of the airbag layer 520 covers a top surface of the punching plate 522 and a part of an edge is connected to the base substrate 510. The entire edge of the cushion unit 521 may be connected to the base substrate 510. Therefore, the punching plate 522 of the airbag layer 520 is disposed in a space between the cushion unit 521 and the base substrate 510 instead of being disposed inside the cushion unit 521.

The plurality of injection holes 510a is formed in the base substrate 510 and the pad unit 511. The plurality of injection holes 510a may overlap at least some of the plurality of holes 522a of the punching plate 522. The plurality of injection holes 510a of the base substrate 510 may be connected to some of the plurality of holes 522a of the punching plate 522. Therefore, air may be injected into the airbag layer 520 through a plurality of injection holes 510a of the base substrate 510. The air is injected to one surface of the airbag layer 520 through the plurality of injection holes 510a formed in the base substrate 510, instead of forming a separate air inlet 121a in the cushion unit 521 of the airbag layer 520. Accordingly, the plurality of injection holes 510a may serve as an air inlet 121a of the airbag layer 520.

Referring to FIG. 6, a plurality of first holes H1 and a plurality of second holes H2 are formed in the head HD to which the donor 500 is fixed.

The plurality of first holes H1 is a hole for injecting the air to the airbag layer 520 through the plurality of injection holes 510a of the base substrate 510. The plurality of first holes H1 overlap the plurality of injection holes 510a and is connected to the plurality of injection holes 510a and the hole 522a of the punching plate 522 to form a path for injecting the air into the cushion unit 521.

The plurality of second holes H2 is a holes for sucking air to fix the donor 500 to the head HD. The plurality of second holes H2 may overlap the remaining area of the base substrate 510 excluding an area where the plurality of injection holes 510a is formed. The plurality of second holes H2 suck air to fix the donor 500 to the head HD by a vacuum sucking method.

In the display device according to another example embodiment of the present disclosure, a plurality of injection holes 510a are formed in the base substrate 510 and the air is injected to one surface of the airbag layer 520 through a plurality of injection holes 510a. In this case, a separate air inlet 121a is not formed on a side surface of the airbag layer 520 and the air is directly injected from the head HD to the airbag layer 520 without connecting the pump, so that the process is simplified. Further, the adhesive layer 140 between the airbag layer 520 and the base substrate 510 is removed and one of the cushion units 521 which cover both surfaces of the punching plate 522 may be omitted so that the overall thickness of the donor 500 may be reduced. In addition, the adhesive layer 140 between the airbag layer 520 and the resin layer may also be removed depending on design. For example, the resin layer 130 may be formed by immediately coating a material which forms the resin layer 130 and then curing the material. In this case, even though the adhesive layer 140 is not disposed, the resin layer 130 may be attached onto the donor 500 so that the adhesive layer 140 may be omitted depending on the design, but is not limited thereto.

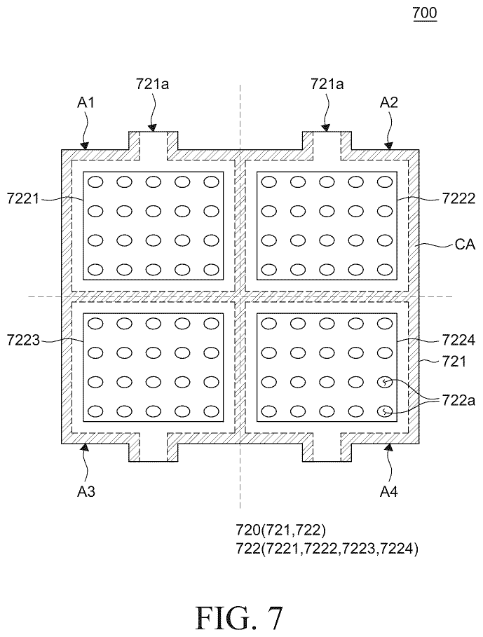

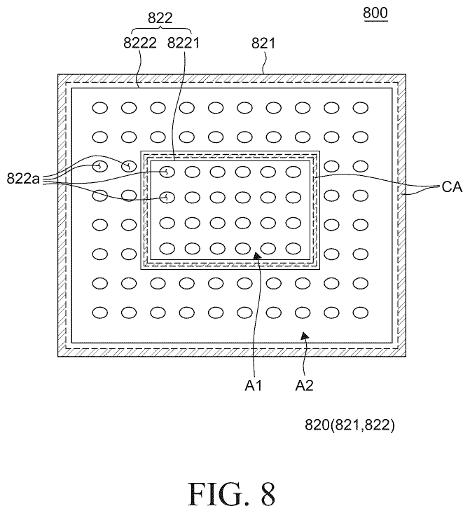

FIG. 7 is a plan view of an airbag layer of a donor according to still another example embodiment of the present disclosure. FIG. 8 is a plan view of an airbag layer of a donor according to still another example embodiment of the present disclosure. Donors 700 and 800 of FIGS. 7 and 8 have airbag layers 720 and 820 having a different structure from those of the donors 100 and 500 of FIGS. 1 to 6, but other configurations are substantially the same so that a redundant description will be omitted or may be briefly provided. Further, in FIGS. 7 and 8, for the convenience of description, punching plates 722 and 822 and a plurality of holes 722a and 822a disposed in cushion units 721 and 821 are illustrated with solid lines.

Referring to FIG. 7, an airbag layer 720 of a donor 700 according to still another example embodiment of the present disclosure includes a plurality of areas to which air is independently injected. The airbag layer 720 is divided into a plurality of areas and individually controls air which is injected to each of the plurality of areas. For example, the airbag layer 720 may include a first area A1 on a left upper end, a second area A2 on a right upper end, a third area A3 on a left lower end, and a fourth area A4 on a right lower end, but embodiments of the present disclosure are not limited thereto.

The plurality of areas of the airbag layer 720 are divided by a connection area CA of the cushion unit 721. The connection area CA may be disposed along a boundary between the plurality of areas and serves as a partition which blocks the flow of the air between the plurality of areas. Therefore, the air which is injected to each area may not flow to the other area by the connection area CA. Therefore, one surface of the cushion unit 721 is connected to the other surface of the cushion unit 721 or one surface of the base substrate 510 at the boundary of the plurality of area to divide the plurality of areas. The top surface portion and the bottom surface portion of the cushion unit 721 are connected to each other at the boundary of the plurality of areas or a connection area CA in which the cushion unit 721 and one surface of the base substrate 510 are connected is formed to inject air to each of the plurality of areas. An amount of air injected to each of the plurality of areas is adjusted to control the pressure of each area to be different. Further, an air injection order may be configured in various ways, by injecting the air to each of the plurality of areas simultaneously or sequentially.

The airbag layer 720 includes a plurality of air inlets 721a to inject air to each of the plurality of areas. For example, the cushion unit 721 of the airbag layer 720 may include four air inlets 721a to inject air to each of the first area A1 to fourth area A4. However, in FIG. 7, it is illustrated that the air inlet 721a extends to a side surface of the airbag layer 720, but like the airbag layer 520 of FIGS. 5 and 6, the air inlet may be formed with a structure which directly injects the air to one surface of the airbag layer 720.

The airbag layer 720 includes a plurality of punching plates 722. The plurality of punching plates 722 may be disposed so as to correspond to each of the plurality of areas. For example, the plurality of punching plates 722 includes a first punching plate 7221 disposed in the first area A1, a second punching plate 7222 disposed in the second area A2, a third punching plate 7223 disposed in the third area A3, and a fourth punching plate 7224 disposed in the fourth area A4.

Referring to FIG. 8, an airbag layer 820 of a donor 800 according to still another example embodiment of the present disclosure includes a plurality of areas to which air is independently injected. For example, the airbag layer 820 may include a first area A1 located in the center of the airbag layer 820 and a second area A2 which encloses or surrounds the first area A1. The second area A2 may be formed with a frame shape. Further, a connection area CA of the cushion unit 821 may include a connection area CA which at least partially encloses or surrounds the first area A1 and a connection area CA which at least partially encloses or surrounds the second area A2.

In this case, the first punching plate 8221 of the plurality of punching plate 822 which is disposed in the first area A1 is formed to have a rectangular shape corresponding to the first area A1. Further, the second punching plate 8222 of the plurality of punching plate 822 which is disposed in the second area A2 is formed to have a frame shape which at least partially encloses or surrounds the first punching plate 8221.

Air may be injected to the first area A1 and the second area A2 by various methods. For example, the air may be directly injected to one surface of the airbag layer 820 in the first area A1 and the second area A2, as illustrated in FIGS. 5 and 6. As another example, in the first area A1, the air is injected to one surface of the airbag layer 820 and in the second area A2, a separate air inlet is formed on the side surface of the second area A2 to inject air.

Further, the air injected to the first area A1 and the second area A2 of the airbag layer 820 is differently controlled so that the chip bump 131 located in the center of the donor 800 and a chip bump 131 located in an outer peripheral portion of the donor 800 may be differently controlled. For example, the air may be injected in the order of the first area A1 and the second area A2 to sequentially attach the chip to the chip bump 131 from the center of the donor to the outer peripheral portion. As another example, when many defects that the light emitting diode LED is not attached to the chip bump 131 occur in the outer peripheral portion of the donor 800, more air is injected into the second area A2 to configure the pressure of the second area A2 to be higher than the pressure of the first area A1. By doing this, the chip bump 131 located in the second area A2 protrudes more.

Accordingly, in the donors 700 and 800 according to still another example embodiment of the present disclosure, the airbag layers 720 and 820 are divided into a plurality of areas to which the air is independently injected to individually control whether the plurality of chip bumps 131 and the light emitting diodes LED are in contact with each other in each area. For example, when only the first area A1 and the second area A2 of the donors 700 and 800 overlap the temporary substrate TS, the air is injected to the first area A1 and the second area A2 to minimize or at least reduce the non-contact defect of the plurality of light emitting diodes LED and the plurality of chip bumps 131. As another example, a pressure of the air which is injected to each of the plurality of areas of the donors 700 and 800 may be controlled to be different in consideration of non-contact defect rate of the plurality of chip bumps 131 and the light emitting diodes LED or a thickness deviation of the donors 700 and 800. Accordingly, the transfer process is performed by dividing the airbag layers 720 and 820 of the donors 700 and 800 into a plurality of areas and selectively injecting the air to each of the plurality of areas according to the situation to reduce the non-transferring defect of the light emitting diode LED and optimize the transfer process.

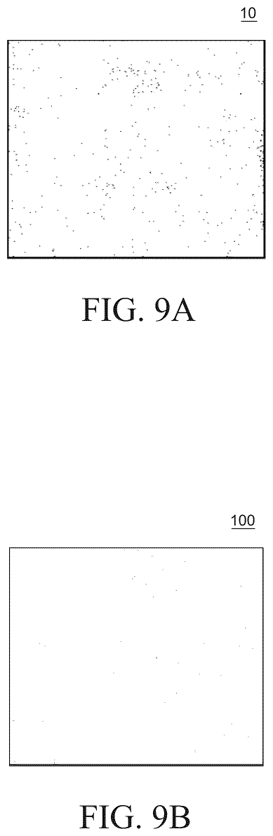

Hereinafter, an effect of improving a transfer defect of the donor 100 according to an example embodiment of the present disclosure will be described in more detail with reference to FIGS. 9A and 9B.

FIG. 9A is an image inspecting a transfer process result using a donor according to a comparative embodiment. FIG. 9B is an image inspecting a transfer process result using a donor according to an example embodiment of the present disclosure.

A donor 10 according to a comparative embodiment has the same configuration as the donor 100 according to the example embodiment of the present disclosure excluding that the airbag layer 120 is not included. For example, the donor 10 according to the comparative embodiment includes a base substrate 110, an adhesive layer 140, a resin layer 130, a plurality of chip bumps 131, and a plurality of dummy bumps 132.

Images of FIGS. 9A and 9B are images obtained by inspecting the donors 10 and 100 after the transfer process of attaching the light emitting diode LED on the temporary substrate TS to the plurality of chip bumps 131 of the donors 10 and 100. A dot displayed on the image indicates a location of a chip bump 131 to which the light emitting diode LED is not attached, among the plurality of chip bumps 131.

Referring to FIG. 9A, the donor 10 according to the comparative embodiment is bonded to the temporary substrate TS to attach the plurality of light emitting diodes LED on the temporary substrate TS to the plurality of chip bumps 131 of the donor 10 according to the comparative embodiment. As a result of inspecting the plurality of chip bumps 131 of the donor 10, it is confirmed that there is a plurality of chip bumps 131 to which the light emitting diode LED is not attached, among the plurality of chip bumps 131.

Referring to FIG. 9B, the donor 100 according to the example embodiment of the present disclosure is bonded to the temporary substrate TS to attach the plurality of light emitting diodes LED on the temporary substrate TS to the plurality of chip bumps 131 of the donor 100 according to the example embodiment of the present disclosure. At this time, air is injected to the airbag layer 120 to minimize or at least reduce a gap G between the plurality of chip bumps 131 and the plurality of light emitting diodes LED during the transfer process, to transfer the light emitting diode LED to the donor 100. Therefore, as a result of inspecting the plurality of chip bumps 131 of the donor 100 according to the example embodiment of the present disclosure, as compared with the inspection result of the donor 10 according to the comparative embodiment, it is confirmed that the chip bumps 131 to which the light emitting diode LED is not attached, among the plurality of chip bumps 131, is significantly reduced.

Accordingly, donors 100, 500, 700, and 800 according to various example embodiments of the present disclosure include an airbag layer 120 which applies a pressure to the plurality of chip bumps 131 to remove the gap G between the plurality of chip bumps 131 and the light emitting diode LED during the transfer process. Accordingly, a case that the plurality of chip bumps 131 and the plurality of light emitting diodes LED are not in contact is minimized or reduced to reduce the transferring defect of the light emitting diode LED.

The example embodiments of the present disclosure can also be described as follows:

According to an aspect of the present disclosure, a donor includes a base substrate, a resin layer which is disposed on the base substrate and includes a plurality of chip bumps, and an airbag layer which is disposed between the base substrate and the resin layer and is configured to be expandable by air injected from the outside.

The airbag layer may be configured to expand to push the resin layer and the plurality of chip bumps in a direction from the bottom of the base substrate to the top of the base substrate.

The airbag layer may include a punching plate including a plurality of holes, and a cushion unit which at least partially encloses or surrounds at least a part of the punching plate and is formed of an elastic material, and the cushion unit may be configured to expand when the air is injected to the airbag layer.

The donor may further include an adhesive layer which is disposed between the airbag layer and the base substrate and between the airbag layer and the resin layer. The cushion unit may be formed by a top surface portion and a bottom surface portion which cover both surfaces of the punching plate.

The cushion unit may further include an air inlet and the top surface portion and the bottom surface portion are connected in a remaining part of an edge of the cushion unit excluding a part corresponding to the air inlet.

The punching plate may be in contact with a top surface of the base substrate and the cushion unit may be connected to the top surface of the base substrate while covering the punching plate.

The base substrate may include a plurality of injection holes which overlaps at least some of the plurality of holes of the punching plate.

The donor may further include a pad unit which covers the remaining part of the bottom surface of the base substrate excluding a part in which the plurality of injection holes is disposed.

The airbag layer may include a plurality of areas, the punching plate may include a plurality of punching plates corresponding to the plurality of areas, and one surface of the cushion unit may be connected to any one of another surface of the cushion unit or one surface of the base substrate at a boundary of the plurality of areas.

According to an aspect of the present disclosure, a transfer method of a light emitting diode using a donor includes loading, a temporary substrate with a plurality of light emitting diodes disposed on a top surface, on a stage, and fixing a donor to a head, bonding the temporary substrate and the donor by moving the head to the stage, injecting air to an airbag layer of the donor, and moving the head to separate the temporary substrate and the donor.

The injecting of air to an airbag layer of the donor may be a step of injecting air to the airbag layer to expand the airbag layer to push a plurality of chip bumps of the donor toward the plurality of light emitting diodes.

In the bonding of the temporary substrate and the donor, at least some of the plurality of chip bumps may have a gap from the plurality of light emitting diodes and in injecting of air to an airbag layer, at least some of the plurality of chip bumps may be in contact with the plurality of light emitting diodes.

The airbag layer may include a plurality of areas to which air is independently injected.

The injecting of air to an airbag layer of the donor may include injecting air to only some areas of the plurality of areas.

The injecting of air to an airbag layer of the donor may include injecting air to each of the plurality of areas, sequentially.

The injecting of air to an airbag layer of the donor may include injecting different amounts of air to each of the plurality of areas.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A donor, comprising:
a base substrate;
a resin layer which is disposed on the base substrate and includes a plurality of chip bumps; and
an airbag layer which is disposed between the base substrate and the resin layer and is configured to be expandable by air injected from the outside.

2. The donor according to claim 1, wherein the airbag layer is configured to expand and push the resin layer and the plurality of chip bumps in a direction from the bottom of the base substrate to a top of the base substrate.

3. The donor according to claim 1, wherein the airbag layer includes:
a punching plate including a plurality of holes; and
a cushion unit which encloses at least a part of the punching plate and includes an elastic material, and
wherein the cushion unit is configured to expand when the air is injected to the airbag layer.

4. The donor according to claim 3,
wherein the cushion unit includes a top surface portion and a bottom surface portion which cover both surfaces of the punching plate.

5. The donor according to claim 4, wherein the cushion unit further includes an air inlet, and
wherein the top surface portion and the bottom surface portion are connected in a remaining part of an edge of the cushion unit excluding a part corresponding to the air inlet.

6. The donor according to claim 3, wherein the punching plate is in contact with a top surface of the base substrate and the cushion unit is connected to the top surface of the base substrate while covering the punching plate.

7. The donor according to claim 6, wherein the base substrate includes a plurality of injection holes which overlaps at least some of the plurality of holes of the punching plate.

8. The donor according to claim 7, further comprising:
a pad unit that covers a remaining part of a bottom surface of the base substrate excluding a part in which the plurality of injection holes are disposed.

9. The donor according to claim 3, wherein the airbag layer includes a plurality of areas, the punching plate includes a plurality of punching plates corresponding to the plurality of areas, and one surface of the cushion unit is connected to any one of another surface of the cushion unit or one surface of the base substrate at a boundary of the plurality of areas.

10. The donor according to claim 3, wherein a fluorine coating layer is formed on one or more surfaces of the punching plate.

11. The donor according to claim 1, further comprising an adhesive layer which is disposed between the airbag layer and the base substrate and between the airbag layer and the resin layer.

12. The donor according to claim 1, wherein the resin layer includes an active area and an inactive area adjacent to the active area, and
wherein the plurality of chip bumps are disposed in the active area, and a plurality of dummy bumps are disposed in the inactive area.

13. A transfer method of a light emitting diode using a donor, comprising:
loading, a temporary substrate with a plurality of light emitting diodes disposed on a top surface, on a stage, and fixing a donor to a head;
bonding the temporary substrate and the donor by moving the head to the stage;
injecting air to an airbag layer of the donor; and
moving the head to separate the temporary substrate and the donor.

14. The transfer method according to claim 13, wherein the injecting of air to the airbag layer of the donor includes injecting air to the airbag layer and expanding the airbag layer to push a plurality of chip bumps of the donor toward the plurality of light emitting diodes.

15. The transfer method according to claim 14, wherein in the bonding of the temporary substrate and the donor, at least some of the plurality of chip bumps has a gap from the plurality of light emitting diodes and in injecting of air to an airbag layer, the at least some of the plurality of chip bumps is in contact with the plurality of light emitting diodes.

16. The transfer method according to claim 14, wherein the airbag layer includes a plurality of areas to which air is independently injected.

17. The transfer method according to claim 16, wherein the injecting of air to the airbag layer of the donor includes injecting air to only some areas of the plurality of areas.

18. The transfer method according to claim 16, wherein the injecting of air to the airbag layer of the donor includes injecting air to each of the plurality of areas, sequentially.

19. The transfer method according to claim 16, wherein the injecting of air to the airbag layer of the donor includes injecting different amounts of air to each of the plurality of areas.

20. A transfer method of a light emitting diode using a donor, comprising:
loading, a target substrate on a stage, and fixing a donor to which a plurality of light emitting diodes are attached to a head;
bonding the target substrate and the donor by moving the head to the stage;
injecting air to an airbag layer of the donor; and
moving the head to separate the target substrate and the donor.
